(19) United States
(12) Patent Application Publication
(10) Pub. No.: US 2004/0207093 A1
(43) Pub. Date: Oct. 21, 2004

(54) Method of fabricating an alloy cap layer over CU wires to improve electromigration performance of CU interconnects

(76) Inventors: Sey-Shing Sun, Portland, OR (US); Byung-Sung Kwak, Portland, OR (US); Jayanthi Pallinti, Gresham, OR (US); William Barth, Gresham, OR (US)

Correspondence Address: LSI LOGIC CORPORATION, 1621 BARBER LANE, MS: D-106 LEGAL, MILPITAS, CA, 95035, US

(21) Appl. No.: 10/417,705

(22) Filed: Apr. 17, 2003

(51) Int. Cl. H01L 23/48

(52) U.S. Cl. 257/765

(57) ABSTRACT

An integrated circuit device which includes a surface alloy layer, where the alloy layer forms a protective and adherent thin layer which improves electromigration performance. A method includes steps of forming one or more trench and/or via structures, depositing a thin TaN/Ta barrier layer stack and then a Copper seed layer, depositing and filling the via/trench with a thick Copper layer, removing the metal layers over in the field area, depositing, for example, a layer of Aluminum over the structure, annealing the devices in a protective atmosphere to allow Aluminum to react with Copper to form a thin Copper-Aluminum alloy, and removing the Aluminum metal layers over the field area, forming a thin layer of Al₂O₃, AlN or Al₃C₄ over the Copper-Aluminum for protection. During subsequent deposition of barrier and seed, the top surface layer of the Al₂O₃, AlN or Al₃C₄ is preferably removed to ensure the integrity of metal contact.

### BACKGROUND

Presently, copper interconnect technology is widely used in the field of advanced, high performance integrated circuit devices. Because Copper has a higher melting point than does Aluminum, it was expected that Copper would have improved current-carrying capability and would have extended electromigration lifetime. However, tests have shown that electromigration lifetime is more dependent on atomic transport at the Copper/dielectric interface, than on the intrinsic character of the Copper lattice or atomic transport at grain boundaries or the Copper/barrier metal interface. As the fraction of atoms at interfaces is increased as the dimension of the interconnection is scaled down, the Copper electromigration lifetime and the allowed current density in Copper interconnect will be reduced in every new generation of technology node. To extend the viability of Copper interconnect technology to smaller dimensions while maintaining high performance and reliability, modification of the interface between Copper/dielectric is needed to reduce Copper transport and void growth.

Several approaches to achieve this purpose have been attempted. Most of them focus on the use of selective deposition techniques, e.g., chemical vapor deposition and electroless deposition, to deposit thin metals, e.g., W, ZrN, CoWB, and CoWP on Copper after Copper Chemical Mechanical Polishing. Significant improvement in electromigration performance resulted from implementing these metal cap layers. Although selective deposition was meant to reduce production cost, the ensuing problems associated with selective deposition—e.g., maturity of the technology for small geometry devices, stringent requirement of surface preparation, poor quality of the metal deposited—all constitute issues that need to be solve before selective deposition can be integrated into production flow. In addition, selective deposition requires that a new set of deposition tools be purchased for this new cap metal process, and this adds to the cost. Furthermore, generally the resistivities of the metals which have been proposed are all significantly higher than Copper, and contribute to higher via resistance, which would negatively affect circuit performance if implemented.

### OBJECTS AND SUMMARY

An object of an embodiment of the present invention provides a structure and method for forming an effective cap metal layer using simple and available processing techniques.

An object of an embodiment of the present invention provides a structure and method wherein a unique series of processing steps are performed to form a unique metal cap layer that has demonstrated Copper diffusion barrier capability, low via resistance and good electromigration performance.

Briefly, and in accordance with at least one of the foregoing objects, a preferred embodiment of the present invention provides an integrated circuit device which includes a surface alloy layer, such as a Copper-Aluminum alloy layer or the like, where the alloy layer forms a protective and adherent thin layer which improves electromigration performance.

Another, preferred embodiment of the present invention provides a method which includes the following steps:

1. Forming one or more trench and/or via structures.

2. Depositing a thin TaN/Ta barrier layer stack, or other barrier materials, e.g., TiN, TiZrN, TiCN, TiSiₓN_{y}, TaSiₓN_{y}, WN, WbₓN_{y}, WcₓN_{y} and then a Copper seed layer. On dielectric materials that are stable against copper diffusion, e.g. barrierless dielectric, copper seed can be deposited directly onto trench and via in dielectric.

3. Depositing and filling the via/trench with a thick Copper layer.

4. Removing the metal layers over in the field area, i.e., the area between trenches.

5. Depositing, for example, a layer of Aluminum over the structure.

6. Annealing the devices in a protective atmosphere to allow Aluminum to react with Copper to form a thin Copper-Aluminum alloy.

7. Removing the Aluminum metal layers over the field area, i.e., the area between trenches.

8. Forming a thin layer of Al₂O₃, AlN, or Al₃C₄ over the Copper-Aluminum for protection.

9. During subsequent deposition of barrier and seed, the top surface layer of Al₂O₃, AlN or Al₃C₄ is preferably removed to ensure the integrity of metal contact.

The present invention provides that the top surface of a Copper conductor is alloyed with Aluminum to form a protective and adherent thin layer to improve EM performance. It is also possible to use other metals, e.g., Mg, Cr, Zr, Zn, In, Sn, B, Ti, that can easily form a stable alloy with Copper to achieve the same purpose.

### BRIEF DESCRIPTION OF THE DRAWINGS

The organization and manner of the structure and operation of the invention, together with further objects and advantages thereof, may best be understood by reference to the following description, taken in connection with the accompanying drawing, wherein:

FIG. 1 illustrates an integrated circuit device which is in accordance with an embodiment of the present invention;

FIG. 2 illustrates a method which is in accordance with an embodiment of the present invention;

FIGS. 3-8 illustrate an integrated circuit device as it is being made in accordance with the method shown in FIG. 2.

### DESCRIPTION

While the invention may be susceptible to embodiment in different forms, there is shown in the drawings, and herein will be described in detail, a specific embodiment with the understanding that the present disclosure is to be considered an exemplification of the principles of the invention, and is not intended to limit the invention to that as illustrated and described herein.

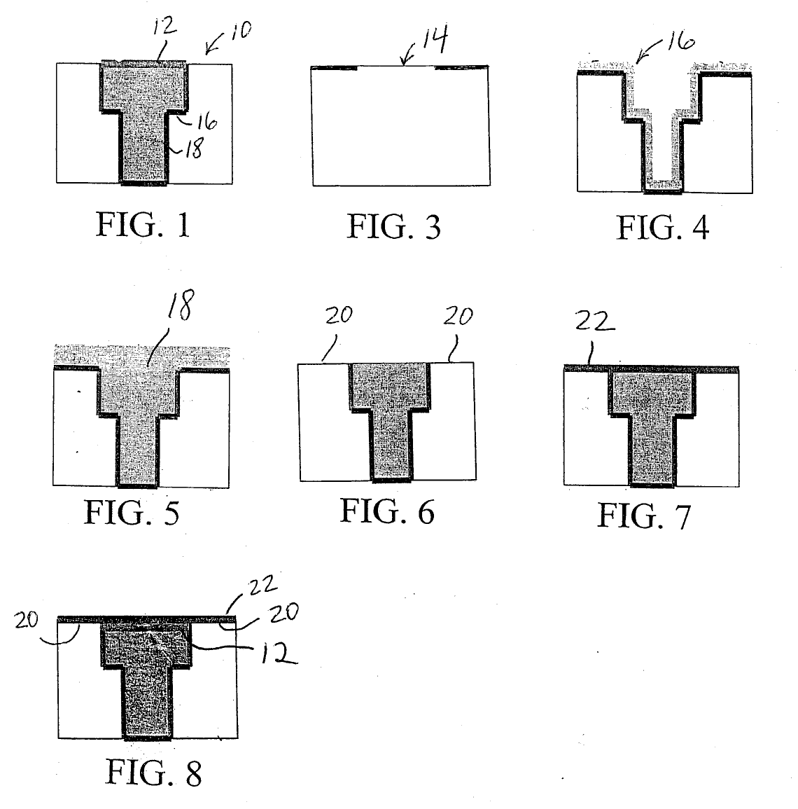

FIG. 1 illustrates an integrated circuit device 10 which is in accordance with an embodiment of the present invention. The integrated circuit device 10 includes a surface alloy layer 12, such as a Copper-Aluminum alloy layer or the like, where the alloy layer 12 forms a protective and adherent thin layer which improves electromigration performance.

FIG. 2 illustrates a method which is in accordance with an embodiment of the present invention, wherein a method of forming the integrated circuit device shown in FIG. 1 is provided. FIGS. 3-8 (and FIG. 1) illustrate the integrated circuit device as it is being made in accordance with the method shown in FIG. 2.

As shown in FIGS. 2-8, the method preferably provides the following steps:

1. Forming a trench and/or via 14. Specifically, a trench or via is formed for Single damascene wiring, and a trench and via structure is formed for Dual damascene wiring (the later is shown in FIG. 3).

2. Depositing a thin TaN/Ta barrier layer stack, or other barrier materials, e.g., TiN, TiZrN, TiCN, TiSiₓN_{y}, TaSiₓN_{y}, WN, WbₓN_{y}, WcₓN_{y} and then a Copper seed layer. On dielectric materials that are stable against copper diffusion, e.g. barrierless dielectric, copper seed can be deposited directly onto trench and via in dielectric (all of which is collectively referenced by reference numeral 16 in FIG. 4), such as by sputtering, chemical vapor deposition or atomic layer deposition.

3. Depositing and filling the via/trench with a thick Copper layer 18 (see FIG. 5), such as by electrochemical plating.

4. Removing the metal layers over in the field area 20, i.e., the area between trenches (see FIG. 6), such as by chemical mechanical polishing or other methods, e.g., electro polishing.

5. Depositing a layer of Aluminum 22 over the structure (see FIG. 7).

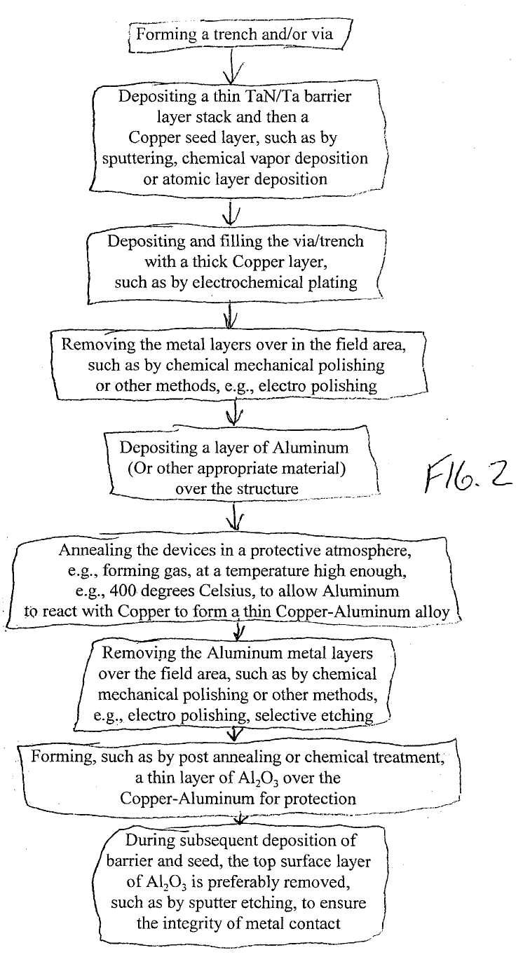

6. Annealing the devices in a protective atmosphere, e.g., forming gas, at a temperature high enough, e.g., 400 degrees Celsius, to allow Aluminum to react with Copper to form a thin Copper-Aluminum alloy 12 (see FIG. 8). Copper-Aluminum is known to be stable with no appreciable Copper out diffusion into SiO₂ at temperature up to 700 degrees Celsius. The resistivity increase is minimal, e.g., 3.7 μΩ-cm for 1 at. % Aluminum in Copper, especially when compared with Co (6.2 μΩ-cm) and W (5.65 μΩ-cm). The impact on via resistance is minimal. Copper-Aluminum alloy also adheres to SiO₂ better than pure Copper and contributes to better EM performance.

7. Removing the Aluminum metal layers 22 over the field area 20, i.e., the area between trenches (see FIG. 1), such as by chemical mechanical polishing or other methods, e.g., electro polishing and selective chemical etching. Due to dishing effect, some Aluminum may remain over the Copper trenches, which is acceptable since the Aluminum also could serve as a barrier with subsequent passivation treatment.

8. Forming, such as by post annealing or chemical treatment, a thin layer of Al₂O₃, AlN or Al₃C₄ over the Copper-Aluminum for protection.

9. During subsequent deposition of barrier and seed, the top surface layer of Al₂O₃, AlN or Al₃C₄ is preferably removed, such as by sputter etching, to ensure the integrity of metal contact.

The present invention provides that the top surface of a Copper conductor is alloyed with Aluminum to form a protective and adherent thin layer to improve EM performance. It is also possible to use other metals, e.g., Mg, Cr, Zr, Zn, In, Sn, B, Ti that can easily form a stable alloy with Copper to achieve the same purpose. Furthermore, the steps can be performed using many different techniques or methods. For example, a technique other than sputtering can be used to deposit the metal overlayer. Other techniques such as chemical vapor deposition, atomic layer deposition and sol-gel deposition can be used instead.

While an embodiment of the present invention is shown and described, it is envisioned that those skilled in the art may devise various modifications of the present invention without departing from the spirit and scope of the appended claims.

1. An integrated circuit device comprising at least one of a trench and a via; Copper fill in at least one of the trench and via; a surface alloy layer over the Copper fill, wherein the alloy layer is a protective and adherent thin layer which improves electromigration performance.

2. An integrated circuit device as recited in claim 1, wherein the alloy layer comprises a Copper-Aluminum alloy.

3. An integrated circuit device as recited in claim 1, further comprising a TaN/Ta barrier layer stack and a Copper seed layer on the TaN/Ta barrier layer stack.

4. A method of forming an integrated circuit device, said method comprising forming a at least one of a trench and a via; filling at least one of the trench and via with Copper; depositing a layer of metal over the Copper; causing the layer of metal to react with the Copper to form an alloy layer between the Copper and the layer of metal; and removing the layer of metal, thereby exposing the alloy layer.

5. A method as recited in claim 4, further comprising depositing a TaN/Ta barrier layer stack and then a Copper seed layer.

6. A method as recited in claim 4, further comprising depositing a TaN/Ta barrier layer stack and then a Copper seed layer by at least one of sputtering, chemical vapor deposition or atomic layer deposition.

7. A method as recited in claim 4, further comprising filling at least one of the trench and via with Copper by electrochemical plating.

8. A method as recited in claim 4, further comprising removing metal layers in a field area.

9. A method as recited in claim 4, further comprising removing metal layers in a field area by at least one of chemical mechanical polishing, electro polishing and selective chemical etching.

10. A method as recited in claim 4, wherein the step of depositing a layer of metal over the Copper comprises depositing a layer of Aluminum over the Copper.

11. A method as recited in claim 4, wherein the step of causing the layer of metal to react with the Copper to form an alloy comprises at least one of annealing and chemically treating the device.

12. A method as recited in claim 4, wherein the step of depositing a layer of metal over the Copper comprises depositing a layer of Aluminum over the Copper, and wherein the step of causing the layer of metal to react with the Copper to form an alloy comprises at least one of annealing and chemically treating the device by forming gas, at a temperature high enough, to allow Aluminum to react with Copper to form a Copper-Aluminum alloy.

13. A method as recited in claim 10, further comprising removing Aluminum over a field area.

14. A method as recited in claim 10, further comprising removing Aluminum over a field area by at least one of chemical mechanical polishing, electro polishing and selective chemical etching.

15. A method as recited in claim 4, further comprising forming a protective layer over the alloy.

16. A method as recited in claim 14, wherein the step of forming a protective layer over the alloy comprises forming a thin layer of at least one of Al₂O₃, AlN or Al₃C₄ over the alloy.

17. A method as recited in claim 10, further comprising forming a thin layer of at least one of Al₂O₃, AlN or Al₃C₄ over the alloy.

18. A method as recited in claim 10, further comprising forming a thin layer of at least one of Al₂O₃, AlN or Al₃C₄ over the alloy by post annealing.

19. A method as recited in claim 14, further comprising removing the protective layer.

20. A method as recited in claim 14, further comprising removing the protective layer by sputter etching.
